(19) United States
(12) Patent Application Publication
(10) Pub. No.: US 2025/0233095 A1
(43) Pub. Date: Jul. 17, 2025

(54) SEMICONDUCTOR CHIP, SEMICONDUCTOR PACKAGE INCLUDING SEMICONDUCTOR CHIP, AND METHOD FOR MANUFACTURING THE SAME

(71) Applicant: Samsung Electronics Co., Ltd., Suwon-si (KR)

(72) Inventor: JAESIC LEE, Suwon-si (KR)

(21) Appl. No.: 18/826,972

(22) Filed: Sep. 6, 2024

(30) Foreign Application Priority Data
Jan. 12, 2024 (KR) 10-2024-0005527

(51) Int. Cl. H01L 23/00; H01L 25/18; H10B 80/00

(52) U.S. Cl. CPC H01L 24/08; H01L 24/03; H01L 24/05; H01L 24/80; H01L 24/16; H01L 25/18; H01L 2224/03831; H01L 2224/05005; H01L 2224/05015; H01L 2224/05017; H01L 2224/08145; H01L 2224/16225; H01L 2224/80895; H01L 2224/80896; H01L 2924/1431; H01L 2924/1436; H10B 80/00

(57) ABSTRACT

A semiconductor chip includes a substrate; a back side bonding structure on a back surface of the substrate; and a front side bonding structure on a front side of the substrate, wherein the back side bonding structure and the front side bonding structure each include: a dielectric layer; and bonding pads configured to extend through the dielectric layer, each of the bonding pads a conductive pad configured to include a bonding region and a peripheral region around the bonding region; and a barrier layer between a side surface of the peripheral region and the dielectric layer, and each of the bonding pads of the back side bonding structure, each of the bonding pads of the front side bonding structure, or both each of the bonding pads of the back side bonding structure and each of the bonding pads of the front side bonding structure includes a trench in which the peripheral region and the barrier layer are recessed based on a level of a bonding surface of the bonding region.

### CROSS-REFERENCE TO RELATED APPLICATION

This application claims priority to and the benefit of Korean Patent Application No. 10-2024-0005527, filed in the Korean Intellectual Property Office on Jan. 12, 2024, the entire contents of which are incorporated herein by reference.

### BACKGROUND

### (a) Field

The present disclosure relates to a semiconductor chip, a semiconductor package including a semiconductor chip, and a manufacturing method therefor.

### (b) Description of the Related Art

In the semiconductor industry, it is becoming increasingly important to make a semiconductor package mounted in an electronic device smaller, lighter, and thinner, while at the same time, having high speed, multifunctionality, and large capacity, in line with a demand for miniaturization of electronic devices. Accordingly, a demand for packaging technology that can store more data and transmit data at a higher speed is increasing, and as such packaging technology, a stacked semiconductor device (e.g., a high bandwidth memory (HBM)), which is formed by stacking a plurality of individual semiconductor chips, is being developed.

Stacked semiconductor devices are manufactured by combining the same type or different types of semiconductor chips, and in the instant case, what is important in combining these semiconductor chips is that the semiconductor chips must be combined with a high 1/O density. If the I/O density is increased and the electrical signal connection density becomes similar to the copper wiring density in a semiconductor front end process, even if the same type or different types of semiconductor chips are combined in a semiconductor back end process, similar results may be produced as a single semiconductor chip made through a semiconductor front end process.

In this way, in order to manufacture bonded semiconductor chips with high 1/O density, a hybrid bonding process may be applied to bond between semiconductor chips. The hybrid bonding involves the bonding of two devices by fusing the same materials of the two devices using a bonding property of the same material. Herein, hybrid indicates that two different types of bonding are made, e.g., bonding two devices with a first type of metal-metal bonding and a second type of non-metal-non-metal bonding.

The hybrid bonding must be performed in a state where each bonding surface of the semiconductor chips to be bonded is flat. A bonding surface of the semiconductor chip on which hybrid bonding is performed includes bonding pads and a dielectric surrounding the sides of the bonding pads, and in the instant case, in a process of exposing the bonding pads from the dielectric covering the bonding pads by performing a chemical mechanical polishing (CMP) process, dishing, in which a central region of the bonding pad is removed more than a peripheral region of the bonding pad, may occur due to a difference in selectivity of different (bonding pad and dielectric) film materials and due to an influence of mechanical processing.

If dishing occurs on the bonding pad, during metal-metal hybrid bonding, central regions of the bonding pads where the bonding occurs may not be bonded to each other, but only the peripheral regions may be bonded to each other. This phenomenon weakens bonding strength and is one of the main causes of peeling of bonding pads.

In addition, if hybrid bonding is performed in a state where each bonding surface of the semiconductor chips is not flat due to variations in surface topography or problems in process technology, vertical lines of bonding surfaces of the bonding pads being bonded may not match.

Due to difference in vertical lines of the bonding surfaces of the bonding pads, each of the bonding surfaces of the misaligned bonding pads may be in contact with a dielectric layer, and cracks may occur because a contacting bonding pad and the dielectric layer are not bonded to each other. Additionally, in the bonding process, corners of the dielectric layer may be broken due to contact impact between the corners of the dielectric layer and the bonding pad.

There is a demand to develop new semiconductor package techniques that can improve these problems.

### SUMMARY

In the process of performing a chemical mechanical polishing (CMP) process to expose bonding pads from a dielectric material covering the bonding pads, when dishing occurs in the bonding pads, a level of a peripheral region of the bonding pad is higher than a level of a central region, a profile slope increases as it moves from the central region to the peripheral region. Accordingly, a bonding pad with a flatter bonding surface may be formed by removing the peripheral region with a large profile slope among the bonding surfaces of the bonding pad.

According to an aspect of the inventive concept, a semiconductor chip includes a substrate; a back side bonding structure on a back surface of the substrate; and a front side bonding structure on a front side of the substrate, wherein the back side bonding structure and the front side bonding structure each comprise: a dielectric layer; and bonding pads extending through the dielectric layer, wherein each of the bonding pads comprises: a conductive pad including a bonding region and a peripheral region around the bonding region; and a barrier layer between a side surface of the peripheral region and the dielectric layer, and each of the bonding pads of the back side bonding structure, each of the bonding pads of the front side bonding structure, or both each of the bonding pads of the back side bonding structure and each of the bonding pads of the front side bonding structure includes a trench in which the peripheral region and the barrier layer are recessed relative to a level of a bonding surface of the bonding region.

According to an aspect of the inventive concept, a semiconductor package includes a first semiconductor die including a first substrate and a first back side bonding structure on a back surface of the first substrate; and a second semiconductor die including a second substrate and a second front side bonding structure on a front side of the second substrate, wherein the second front side bonding structure is bonded to the first back side bonding structure, wherein the first back side bonding structure comprises: a first dielectric layer; and first bonding pads configured to extend through the first dielectric layer, wherein each of the first bonding pads comprises: a first conductive pad including a first bonding region and a first peripheral region around the first bonding region; and a first barrier layer between a side surface of the first peripheral region and the first dielectric layer, wherein the second front side bonding structure comprises: a second dielectric layer; and second bonding pads extending through the second dielectric layer, wherein each of the second bonding pads comprises: a second conductive pad including a second bonding region and a second peripheral region around the second bonding region; and a second barrier layer between a side surface of the second peripheral region and the second dielectric layer, wherein each of the first bonding pads includes a first trench in which the first peripheral region and the first barrier layer are recessed relative to a level of a bonding surface of the first bonding region, each of the second bonding pads includes a second trench in which the peripheral region and the second barrier layer are recessed relative to a level of a bonding surface of the second bonding region, or each of the first bonding pads includes the first trench and each of the second bonding pads includes the second trench.

According to an aspect of the inventive concept, a manufacturing method for a semiconductor chip includes forming a dielectric layer and bonding pads extending through the dielectric layer on a surface of a substrate, each of the bonding pads comprising: a conductive pad; and a barrier layer between a side surface of the conductive pad and the dielectric layer; —forming a sacrificial dielectric layer on the dielectric layer and the bonding pads; forming a pattern on the sacrificial dielectric layer to expose bonding surfaces of the bonding pads; etching the pattern of the sacrificial dielectric layer and performing a chamfering process on the dielectric layer around the bonding pads; and forming a trench in each of the bonding pads such that the barrier layer and a peripheral region of the conductive pad are recessed with respect to a bonding region of each of the bonding pads.

The bonding pad may include a conductive pad and a barrier layer, and the bonding pad may include a trench in which the peripheral region of the conductive pad and the barrier layer are recessed relative to a level of a bonding surface of the bonding region of the conductive pad. As a result, a design margin for a thickness of the bonding pad, which was set in consideration of dishing of the bonding pad, may be improved. Accordingly, bonding strength of the bonding pads may be strengthened to eliminate factors that impede reliability in a case of bonding the bonding pads.

Additionally, the bonding structure for performing hybrid bonding may include a dielectric layer including corner portions chamfered (e.g., rounded) around the bonding pads. With this shape of the dielectric layer, a space may be secured between corners of the dielectric layer and the bonding pads to prevent the dielectric layer and the bonding pads from contacting each other. As a result, during the bonding process, the corners of the dielectric layer are prevented from being broken due to contact impact between the corners of the dielectric layer and the bonding pad, and reliability may be improved.

### BRIEF DESCRIPTION OF THE DRAWINGS

FIG. 1 illustrates a cross-sectional view showing a first semiconductor die according to an embodiment.

FIG. 2 illustrates a cross-sectional view showing a region B of the first semiconductor die of FIG. 1.

FIG. 3 illustrates a bottom plan view of the region B of the first semiconductor die of FIG. 1.

FIG. 4 illustrates a cross-sectional view showing a region C of the first semiconductor die of FIG. 1.

FIG. 5 illustrates a top plan view of the region C of the first semiconductor die of FIG. 1.

FIG. 6 illustrates a cross-sectional view showing a first semiconductor stacking structure according to an embodiment.

FIG. 7 illustrates a cross-sectional view showing a region D of the first semiconductor stacking structure of FIG. 6.

FIG. 8 illustrates a cross-sectional view showing another embodiment of the region D of the first semiconductor stacking structure of FIG. 6.

FIG. 9 illustrates a cross-sectional view showing another embodiment of the region D of the first semiconductor stacking structure of FIG. 6.

FIG. 10 illustrates a cross-sectional view showing a semiconductor package according to an embodiment.

FIG. 11 illustrates a cross-sectional view showing a second semiconductor stacking structure according to an embodiment.

FIG. 12 illustrates a cross-sectional view showing a semiconductor package according to an embodiment.

FIG. 13 to FIG. 34 illustrate cross-sectional views for describing a manufacturing method for the first semiconductor die of FIG. 1.

### DETAILED DESCRIPTION

The present disclosure will be described more fully hereinafter with reference to the accompanying drawings, in which embodiments of the disclosure are shown. As those skilled in the art would realize, the described embodiments may be modified in various different ways, all without departing from the spirit or scope of the inventive concept.

To clearly describe the present disclosure, parts that are irrelevant to the description in the drawings are omitted, and like numerals refer to like or similar constituent elements throughout the specification.

Further, since sizes and thicknesses of constituent members shown in the accompanying drawings are arbitrarily given for better understanding and ease of description, the present disclosure is not limited to the illustrated sizes and thicknesses.

Throughout this specification and the claims that follow, when it is described that an element is “coupled/connected” to another element, the element may be “directly coupled/connected” to the other element or “indirectly coupled/connected” to the other element through a third element. In addition, unless explicitly described to the contrary, the word “comprise” and variations such as “comprises” or “comprising” will be understood to imply the inclusion of stated elements but not the exclusion of any other elements.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on or below the object portion, and does not necessarily mean positioned on the upper side of the object portion based on a gravitational direction.

Further, throughout the specification, the phrase “in a plan view” means when an object portion is viewed from above, and the phrase “in a cross-sectional view” means when a cross-section taken by vertically cutting an object portion is viewed from the side.

Throughout the specification, when a component is described as “including” a particular element or group of elements, it is to be understood that the component is formed of only the element or the group of elements, or the element or group of elements may be combined with additional elements to form the component, unless the context clearly and/or explicitly describes the contrary. The term “consisting of,” on the other hand, indicates that a component is formed only of the element(s) listed.

The disclosed “layers” may each be a single homogeneous layer (formed of the same base material throughout). For example, the disclosed “layers” may each be formed with a single corresponding process (e.g., in situ—in a chamber without vacuum break to the chamber).

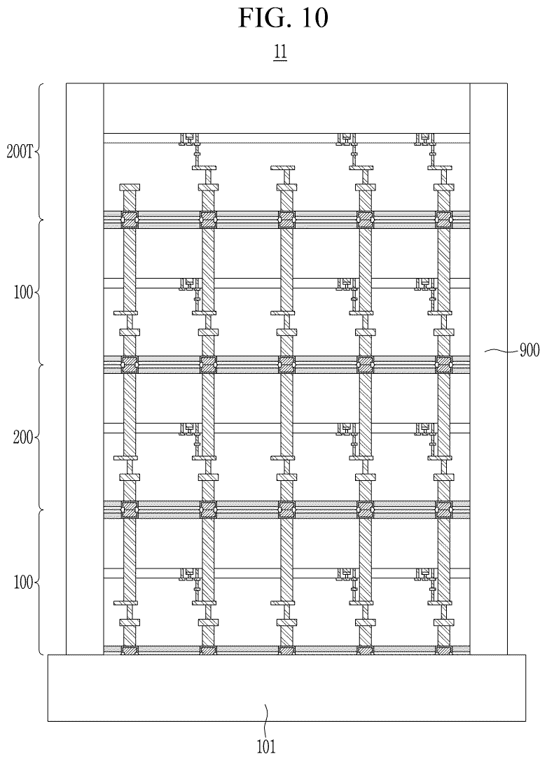

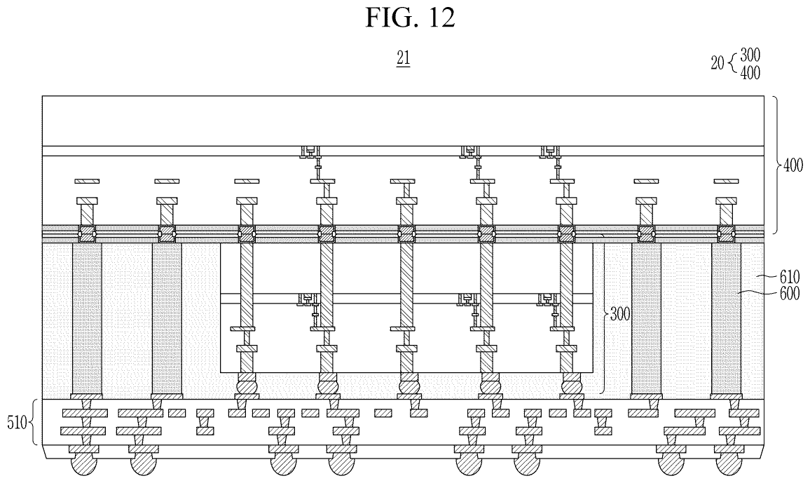

Hereinafter, a semiconductor package 11 (see, e.g., FIG. 10) including a first semiconductor die 100 and a second semiconductor die 200, a semiconductor package 21 (see, e.g., FIG. 12) including a third semiconductor die 300 and a fourth semiconductor die 400 according to an embodiment, and a method of manufacturing a first front side bonding structure 150 of the first semiconductor die 100 will be described with reference to the drawings.

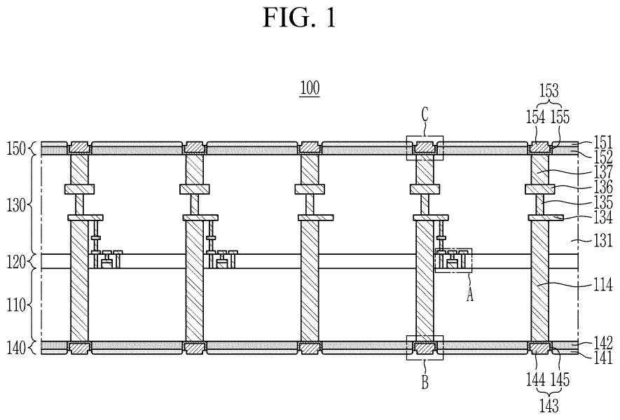

FIG. 1 illustrates a cross-sectional view showing a first semiconductor die 100 according to an embodiment.

Referring to FIG. 1, the first semiconductor die 100 includes a substrate 110, an active layer 120, a wiring layer 130, through silicon vias (TSV) 114, a first front side bonding structure 150, and a first back side bonding structure 140. In an embodiment, the first semiconductor die 100 may be a semiconductor die used in a semiconductor stacking structure, such as a high bandwidth memory (HBM) or a 3D integrate circuit (3DIC).

The active layer 120, the wiring layer 130, and a first front side bonding structure 150 are positioned on a front side of the substrate 110, and the first back side bonding structure 140 is positioned on a back surface of the substrate 110. The through silicon vias (TSV) 114 extend through the substrate 110.

The substrate 110 may be a die formed from a wafer. In an embodiment, the substrate 110 may include silicon or other semiconductor material. In an embodiment, the substrate 110 may include a well doped with an impurity or a structure doped with an impurity. The substrate 110 may have various device isolation structures such as a shallow trench isolation (STI) structure. In an embodiment, the substrate 110 is made of bulk silicon, silicon-on-insulator (SOI), silicon substrate, silicon germanium, silicon germanium-on-insulator (SGOI), silicon carbide, indium antimonide, lead tellurium compound, indium arsenide, indium phosphide, gallium arsenide or gallium antimonide.

The active layer 120 is disposed on a front side of the substrate 110. The active layer 120 is disposed on the substrate 110 in a front-end-of-line (FEOL) process of a front end semiconductor process. The active layer 120 includes an integrated circuit structure A with integrated circuit regions. In an embodiment, the integrated circuit structure A may include at least one of an active device and a passive device. In an embodiment, the integrated circuit structure A may include a gate structure, a source region, and a drain region. In an embodiment, the integrated circuit structure A may include at least one of a transistor, a diode, a capacitor, an inductor, and a resistor.

In an embodiment, the integrated circuit structure A may include at least one of a memory device and a logic device. The memory device may include a volatile memory element or a non-volatile memory device. In an embodiment, the volatile memory device may include a dynamic random access memory (DRAM), a static RAM (SRAM), a thyristor RAM (TRAM), a zero capacitor RAM (ZRAM), a twin transistor RAM (TTRAM), or the like. In an embodiment, the non-volatile memory device may include a flash memory, a magnetic RAM (MRAM), a spin-transfer torque MRAM (STT-MRAM), a ferroelectric RAM (FRAM), a phase change RAM (PRAM), a resistive RAM (RRAM), or the like. In an exemplary embodiment, the logic device may include a microprocessor, a graphics processor, a signal processor, a network processor, codec or the like.

The wiring layer 130 is disposed on the front side of the substrate 110. The wiring layer 130 is disposed on the active layer 120 in a back-end-of-line (BEOL) process of a back end semiconductor process. The wiring layer 130 includes wiring lines 134 and 136, contact plugs 135 and 137, and an intermetal dielectric (IMD) 131.

The wiring lines 134 and 136 and the contact plugs 135 and 137 are signal wires that transmit signals between each device or power wires that transmits power to each device. The wiring lines 134 and 136 are patterned in a horizontal direction to transfer signals and power between layers at the same level. The contact plugs 135 and 137 are vertically patterned to interconnect wiring lines 134 and 136 so as to transfer signals and power between different level layers.

In an embodiment, the wiring lines 134 and 136 and the contact plugs 135 and 137 may each include at least one of copper, aluminum, tungsten, nickel, gold, tin, titanium, and an alloy thereof. In another embodiment, a wiring layer 130 including fewer or more wiring lines and contact plugs is included within the scope of the present disclosure.

The intermetal dielectric (IMD) 131 buries and insulates the wiring lines 134 and 136 and the contact plugs 135 and 137. In an embodiment, the intermetal dielectric (IMD) 131 may include a silicon oxide, a silicon nitride, a silicon oxynitride, a TEOS forming oxide, a PSG, a BPSG, a low-k dielectric material, other suitable dielectric material, or a combination thereof.

The through silicon vias (TSV) 114 extend from the front side to the back surface of the substrate 110. The through silicon vias (TSV) 114 are formed in the BEOL process of the front-end semiconductor process. In an embodiment, the through silicon vias (TSV) 114 may extend from the intermetal dielectric (IMD) 131 of the wire layer 130 into the substrate 110 through the active layer 120. In another embodiment, the through silicon vias (TSV) 114 may extend from the active layer 120 into the substrate 110. In an embodiment, a first end of the through silicon via (TSV) 114 may be connected to the first bonding pad 143 of the first back side bonding structure 140, and a second end of the through silicon via (TSV) 114 may be connected to the wiring line 134 of the wiring layer 130. In another embodiment, the second end of the through silicon via (TSV) 114 may be connected to a wire line of the active layer 120.

The first back side bonding structure 140 is positioned on the back surface of the substrate 110. The first back side bonding structure 140 includes a first dielectric layer 141, a second dielectric layer 142, and first bonding pads 143.

The various pads described herein may generally have a planar upper surface having horizontal dimensions (e.g., in both the X and Y directions) that are both larger than wiring to which the pad is connected to facilitate connections thereto (e.g., to provide a larger surface to contact with a previously or later formed via). For example, a pad may be discretely formed such that it is not in contact with any wiring formed at its vertical level within the device and is only connected to wiring within the device by vias. From a top down view, a pad may have a symmetrical shape (e.g., a circular, square, or rectangular footprint) and may have X and Y horizontal dimensions that are about the same (e.g., within half to two times of the other).

The first dielectric layer 141 is disposed on the back surface of the substrate 110. The first dielectric layer 141 is a layer in which non-metal-non-metal hybrid bonding is performed with a dielectric layer of another semiconductor die. The first dielectric layer 141 includes corner portions (e.g., edge portions) that are chamfered (e.g., rounded) around the first bonding pads 143. In an embodiment, first dielectric layer 141 may include a silicon nitride. In an embodiment, the first dielectric layer 141 may include SiN or SiCN. In an embodiment, a thickness of the first dielectric layer 141 in a vertical direction may be about 0.05 μm to about 1 μm.

The second dielectric layer 142 is disposed between the substrate 110 and the first dielectric layer 141. In an embodiment, the second dielectric layer 142 may include a silicon oxide, a tetraethyl orthosilicate (TEOS) forming oxide, or a combination thereof. In an embodiment, a thickness of the second dielectric layer 142 in the vertical direction may be about 0.1 μm to about 7 μm.

The first bonding pads 143 are positioned to extend through the first dielectric layer 141 and the second dielectric layer 142. The first bonding pads 143 are electrically connected to the through silicon via (TSV) 114. Each of the first bonding pads 143 includes a first conductive pad 144 and a first barrier layer 145. The first bonding pad 143 includes a trench in which a portion of the first conductive pad 144 and the first barrier layer 145 are recessed relative to a level of a bonding surface of the first conductive pad 144.

The first conductive pad 144 is a pad on which metal-metal hybrid bonding is performed with bonding pads of other semiconductor dies, and an electrical connection is made between the first back side bonding structure 140 and another semiconductor die by metal-metal hybrid bonding. The first barrier layer 145 is provided at an interface between the first conductive pad 144 and a stack of the first dielectric layer 141 and the second dielectric layer 142.

The first barrier layer 145 prevents a conductive material of the first conductive pad 144 from diffusing into the first dielectric layer 141 and the second dielectric layer 142 to prevent short circuits between wires. In addition, oxidation chemical reactions that may occur between the first conductive pad 144 and the first dielectric layer 141 and between the first conductive pad 144 and the second dielectric layer 142 are prevented, and chemical stability between structures is increased.

A level of bonding surfaces of the first bonding pads 143 is the same as the level of the bonding surface of the first dielectric layer 141. Side surfaces of the first bonding pads 143 are surrounded by the first dielectric layer 141 and the second dielectric layer 142. In an embodiment, a width of the first bonding pads 143 in the horizontal direction may be about 0.01 μm to about 30 μm. In an embodiment, a depth of the first bonding pads 143 in the vertical direction may be about 0.1 μm to about 7 μm. In an embodiment, a thickness of the first barrier layer 145 in the vertical direction may be about 0.001 μm to about 1 μm.

The first front side bonding structure 150 is positioned on the front side of the substrate 110. The first front side bonding structure 150 is positioned on the wiring layer 130. The first front side bonding structure 150 includes a third dielectric layer 151, a fourth dielectric layer 152, and second bonding pads 153.

The third dielectric layer 151 is disposed on the front side of the substrate 110. The third dielectric layer 151 is a layer in which non-metal-non-metal hybrid bonding is performed with a dielectric layer of another semiconductor die. The third dielectric layer 151 includes corner portions (e.g., edge portions) that are chamfered (e.g., rounded) around the second bonding pads 153. In an embodiment, the third dielectric layer 151 may include a silicon nitride. In an embodiment, the third dielectric layer 151 may include SiN or SiCN. In an embodiment, a thickness of the third dielectric layer 151 in a vertical direction may be about 0.05 μm to about 1 μm.

The fourth dielectric layer 152 is disposed between the wiring layer 130 and the third dielectric layer 151. In an embodiment, the fourth dielectric layer 152 may include a silicon oxide, a TEOS forming oxide, or a combination thereof. In an embodiment, a thickness of the fourth dielectric layer 152 in the vertical direction may be about 0.1 μm to about 7 μm.

The second bonding pads 153 are positioned to extend through the third dielectric layer 151 and the fourth dielectric layer 152. The second bonding pads 153 are electrically connected to the contact plugs 137 of the wiring layer 130. Each of the second bonding pads 153 includes a second conductive pad 154 and a second barrier layer 155. The second bonding pad 153 includes a trench in which a portion of the second conductive pad 154 and the second barrier layer 155 are recessed relative to a level of a bonding surface of the second conductive pad 154.

The second conductive pad 154 is a pad on which metal-metal hybrid bonding is performed with bonding pads of other semiconductor dies, and an electrical connection is made between the first front side bonding structure 150 and another semiconductor die by metal-metal hybrid bonding. The second barrier layer 155 is provided at an interface between the second conductive pad 154 and a stack of the third dielectric layer 151 and the fourth dielectric layer 152.

The second barrier layer 155 prevents a conductive material of the second conductive pad 154 from diffusing into the third dielectric layer 151 and the fourth dielectric layer 152 to prevent short circuits between wires. In addition, oxidation chemical reactions that may occur between the second conductive pad 154 and the third dielectric layer 151 and between the second conductive pad 154 and the fourth dielectric layer 152 are prevented, and chemical stability between structures is increased.

A level of bonding surfaces of the second bonding pads 153 is the same as the level of the bonding surface of the third dielectric layer 151. Side surfaces of the second bonding pads 153 are surrounded by the third dielectric layer 151 and the fourth dielectric layer 152. In an embodiment, a width of the second bonding pads 153 in the horizontal direction may be about 0.01 μm to about 30 μm. In an embodiment, a depth of the second bonding pads 153 in the vertical direction may be about 0.1 μm to about 7 μm. In an embodiment, a thickness of the second barrier layer 155 in the vertical direction may be about 0.001 μm to about 1 μm.

In another embodiment, each of the first bonding pads 143 of the first back side bonding structure 140 may not include a trench, and each of the second bonding pads 153 of the first front side bonding structure 150 may include a trench in which a portion of the second conductive pad 154 and the second barrier layer 155 are recessed relative to the level of the bonding surface of the second conductive pad 154. In another embodiment, each of the second bonding pads 153 of the first front side bonding structure 150 may not include a trench, and each of the first bonding pads 143 of the first back side bonding structure 140 may include a trench in which a portion of the first conductive pad 144 and the first barrier layer 145 are recessed relative to the level of the bonding surface of the first conductive pad 144.

In another embodiment, the first dielectric layer 141 may not include corner portions that are chamfered around the first bonding pads 143, and the third dielectric layer 151 may include corner portions that are chamfered around the second bonding pads 153. In another embodiment, the third dielectric layer 151 may not include corner portions that are chamfered around the second bonding pads 153, and the first dielectric layer 141 may include corner portions that are chamfered around the first bonding pads 143.

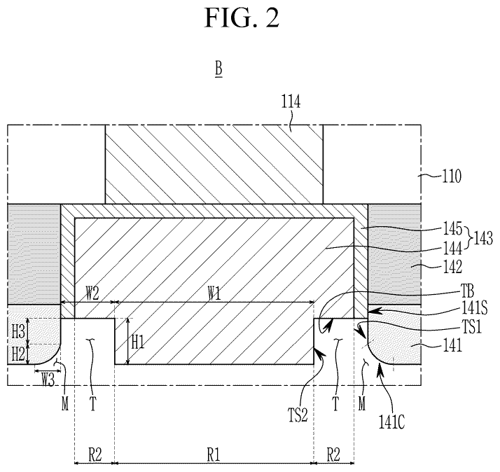

FIG. 2 illustrates a cross-sectional view showing a region B of the first semiconductor die 100 of FIG. 1.

Referring to FIG. 2, the first back side bonding structure 140 includes a first dielectric layer 141, a second dielectric layer 142, and first bonding pads 143.

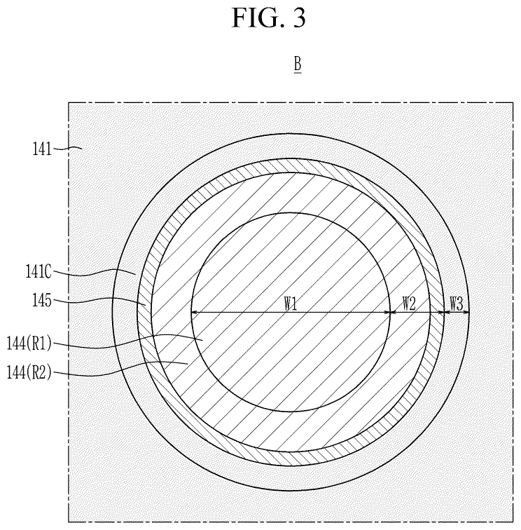

The first dielectric layer 141 includes a corner portion 141C that is chamfered (M) around the first bonding pad 143 and an inner side portion 141S extending vertically from the corner portion 141C. The corner portion 141C and the inner side portion 141S surround the first bonding pad 143. The corner portion 141C may have a shape of a corner when viewed in cross-section as shown, e.g., in FIG. 2, and may have a shape of an edge when viewed in plan view as shown, e.g., in FIG. 3.

At least a portion of the inner side portion 141S of the first dielectric layer 141 is exposed through a trench T. At least a portion of the inner side portion 141S of the first dielectric layer 141 is defined as a first inner surface TS1 of the trench T. In an embodiment, the corner portion 141C of the first dielectric layer 141 has a rounded shape. The first dielectric layer 141 surrounds the side surface of the first bonding pad 143. In an embodiment, the first dielectric layer 141 may contact a portion of the side surface of the first barrier layer 145. In another embodiment, if the trench T is formed deeper than the thickness of the first dielectric layer 141, the first dielectric layer 141 may not contact the side surface of the first barrier layer 145.

The second dielectric layer 142 surrounds the side surface of the first bonding pad 143. In an embodiment, the second dielectric layer 142 may contact a portion of the side surface of the first barrier layer 145. In another embodiment, if the trench T is formed deeper than the thickness of the first dielectric layer 141, the second dielectric layer 142 may contact all sides of the first barrier layer 145.

Each of the first bonding pads 143 includes a first conductive pad 144 and a first barrier layer 145. The first conductive pad 144 has a first surface corresponding to the bonding surface and a second surface opposite to the first surface in the vertical direction. The through silicon via (TSV) 114 is positioned on the second surface of the first conductive pad 144. The first conductive pad 144 includes a first bonding region (first central region) R1 and a first peripheral region R2. The first bonding region R1 has a structure protruded from the first peripheral region R2 in the vertical direction. The first bonding region R1 has a bonding surface (first surface) that may be bonded to a conductive pad of another semiconductor die. The bonding surface has the same level as a surface (e.g., a bonding surface) of the first dielectric layer 141. The first bonding region R1 has a side surface defined by a second inner side TS2 of the trench T as shown, e.g., in FIG. 2.

The first peripheral region R2 has a recessed shape based on the level of the bonding surface of the first bonding region R1. Except for a portion exposed through the trench T, the first peripheral region R2 is surrounded by the first barrier layer 145.

The first barrier layer 145 is disposed between the through silicon via (TSV) 114 and the first conductive pad 144, and electrically connects the through silicon via (TSV) 114 to the first conductive pad 144. The first barrier layer 145 surrounds the side surface of the first peripheral region R2 of the first conductive pad 144 and the second surface of the first conductive pad 144. The first barrier layer 145 conformally extends along the side surface of the first peripheral region R2 of the first conductive pad 144 and the second surface of the first conductive pad 144. The first barrier layer 145 has a recessed shape relative to the level of the bonding surface of the first bonding region R1. For example, the first barrier layer 145 may not protrude as far in the vertical direction as the first bonding region R1 of the first conductive pad 144. In an embodiment, the first barrier layer 145 may be interposed between the side surface of the first peripheral region R2 of the first conductive pad 144 and the first dielectric layer 141, between the side surface of the first peripheral region R2 of the first conductive pad 144 and the second dielectric layer 142, and between the second surface of the first conductive pad 144 and the substrate 110. In an embodiment, the first barrier layer 145 may be provided between the side surface of the first peripheral region R2 of the first conductive pad 144 and the second dielectric layer 142 and between the second surface of the first conductive pad 144 and the substrate 110. In an embodiment, a thickness of the first barrier layer 145 may be about 0.01 μm to about 1 μm.

The first bonding pad 143 includes the trench T. The trench T is defined by a first inner surface TS1, a second inner surface TS2, and a trench bottom TB. The first inner surface TS1 of the trench T is defined by the inner surface (e.g., inner side portion 141S) of the first dielectric layer 141. The second inner surface TS2 of the trench T is defined by the side surface of the first bonding region R1 of the first conductive pad 144. The trench bottom surface TB of the trench T is defined by an exposed surface of the first peripheral region R2 of the first conductive pad 144 and an exposed surface of the first barrier layer 145.

FIG. 3 illustrates a bottom plan view of the region B of the first semiconductor die 100 of FIG. 1.

Referring to FIGS. 2 and 3, the first peripheral area R2 of the first conductive pad 144 is positioned around the first bonding region R1 of the first conductive pad 144. The first barrier layer 145 conformally surrounds the first conductive pad 144. The first dielectric layer 141 conformally surrounds the first barrier layer 145. In an embodiment, the first conductive pad 144, the first barrier layer 145, and the corner portion 141C of the first dielectric layer 141 may have a circular shape. In another embodiment, the first conductive pad 144, the first barrier layer 145, and the corner portion 141C of the first dielectric layer 141 are not limited to the circular shape, and may have various shapes such as a polygon or an oval. In an embodiment, the trench T may include a ring-shaped planar shape extending along the trench bottom surface TB between the first inner surface TS1 and the second inner surface TS2.

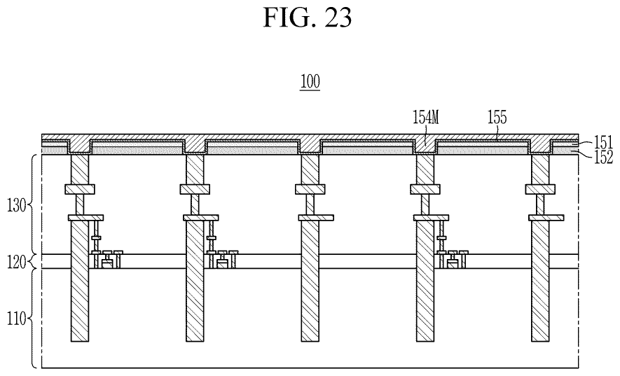

In an embodiment, a horizontal width W1 of the first bonding region R1 may be about 0.006 μm to about 20 μm. In an embodiment, a horizontal width W2 of the trench T may be about 0.002 μm to about 5 μm. In an embodiment, a horizontal width W3 of the corner portion 141C may be about 0.001 μm to about 3 μm. In an embodiment, a height H1 of the second inner surface TS2 of the trench T may be about 0.001 μm to about 2 μm. In an embodiment, a vertical depth H2 of the corner portion 141C may be about 0.001 μm to about 2 μm. In an embodiment, a height H3 of the first inner surface TS1 of the trench T may be about 2 μm or less. The width W3 and the depth H2 of the corner portion 141C may be determined by adjusting the vertical thickness T of the fifth dielectric layer 156 (see FIG. 23) used when performing a chamfering process. The width W3 and the depth H2 of the corner portion 141C may be determined independently.

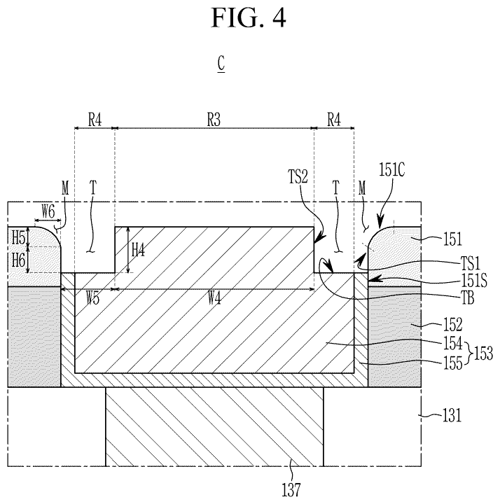

FIG. 4 illustrates a cross-sectional view showing a region C of the first semiconductor die 100 of FIG. 1.

Referring to FIG. 4, the first front side bonding structure 150 includes a third dielectric layer 151, a fourth dielectric layer 152, and second bonding pads 153.

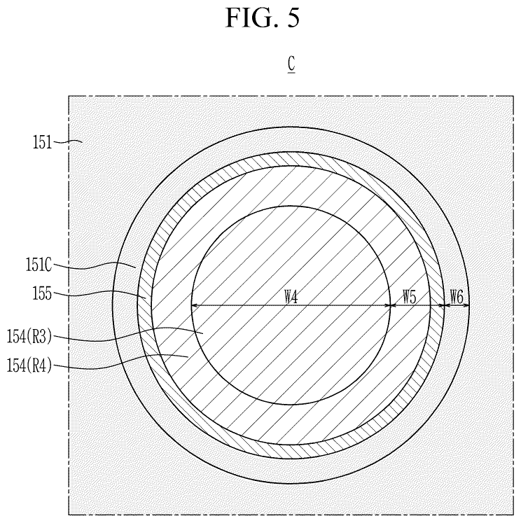

The third dielectric layer 151 includes a corner portion 141C that is chamfered (M) around the second bonding pad 153 and an inner side portion 151S extending vertically from the corner portion 151C. The corner portion 151C and the inner side portion 151S surround the second bonding pad 153. The corner portion 151C may have a shape of a corner when viewed in cross-section as shown, e.g., in FIG. 4, and may have a shape of an edge when viewed in plan view as shown, e.g., in FIG. 5.

At least a portion of the inner side portion 151S of the third dielectric layer 151 is exposed through a trench T. At least a portion of the inner side portion 151S of the third dielectric layer 151 is defined as a first inner surface TS1 of the trench T. In an embodiment, corners of the third dielectric layer 151 (e.g., the corner portion 151C) have a rounded shape. The third dielectric layer 151 surrounds the side surface of the second bonding pad 153. In an embodiment, the third dielectric layer 151 may contact a portion of the side surface of the second barrier layer 155. In another embodiment, if the trench T is formed deeper than the thickness of the third dielectric layer 151, the third dielectric layer 151 may not contact the side surface of the second barrier layer 155.

The fourth dielectric layer 152 surrounds the side surface of the second bonding pad 153. In an embodiment, the fourth dielectric layer 152 may contact a portion of the side surface of the second barrier layer 155. In another embodiment, if the trench T is formed deeper than the thickness of the third dielectric layer 151, the fourth dielectric layer 152 may contact all sides of the second barrier layer 155.

The second bonding pad 153 includes a second conductive pad 154 and a second barrier layer 155. The second conductive pad 154 has a first surface corresponding to the bonding surface and a second surface opposite to the first surface in the vertical direction. A contact plug 137 is positioned on the second surface of the second bonding pad 153. The second conductive pad 154 includes a second bonding region (second center region) R3 and a second peripheral region R4. The second bonding region R3 has a structure protruded from the second peripheral region R4 in the vertical direction. The second bonding region R3 has a bonding surface (first surface) that may be bonded to a conductive pad of another semiconductor die. The bonding surface has the same level as a surface (e.g., a bonding surface) of the third dielectric layer 151. The second bonding region R3 has a side surface defined by a second inner side TS2 of the trench T as shown, e.g., in FIG. 4.

The second peripheral region R4 has a recessed shape relative to the level of the bonding surface of the second bonding region R3. Except for a portion exposed through the trench T, the second peripheral region R4 is surrounded by the second barrier layer 155.

The second barrier layer 155 is disposed between the contact plug 137 and the second conductive pad 154, and electrically connects the contact plug 137 to the second conductive pad 154. The second barrier layer 155 surrounds the side surface of the second peripheral region R4 of the second conductive pad 154 and the second surface of the second conductive pad 154. The second barrier layer 155 conformally extends along the side surface of the second peripheral region R4 of the second conductive pad 154 and the second surface of the second conductive pad 154. The second barrier layer 155 has a recessed shape relative to the level of the bonding surface of the second bonding region R3. For example, the second barrier layer 155 may not protrude as far in the vertical direction as the second bonding region R3 of the second conductive pad 154. In an embodiment, the second barrier layer 155 may be provided between the side surface of the second peripheral region R4 of the second conductive pad 154 and the third dielectric layer 151, between the side surface of the second peripheral region R4 of the second conductive pad 154 and the fourth dielectric layer 152, and between the second surface of the second conductive pad 154 and the wiring layer 130. In an embodiment, the second barrier layer 155 may be interposed between the side surface of the second peripheral region R4 of the second conductive pad 154 and the fourth dielectric layer 152 and between the second surface of the second conductive pad 154 and the wiring layer 130. In an embodiment, a thickness of the second barrier layer 155 in the vertical direction may be about 0.01 μm to about 1 μm.

The second bonding pad 153 includes the trench T. The trench T is defined by a first inner surface TS1, a second inner surface TS2, and a trench bottom TB. The first inner surface TS1 of the trench T is defined by the inner surface (e.g., inner side portion 151S) of the third dielectric layer 151. The second inner surface TS2 of the trench T is defined by the side surface of the second bonding region R3 of the second conductive pad 154. The trench bottom surface TB of the trench T is defined by an exposed surface of the second peripheral region R4 of the second conductive pad 154 and an exposed surface of the second barrier layer 155.

FIG. 5 illustrates a top plan view of the region C of the first semiconductor die 100 of FIG. 1.

Referring to FIGS. 4 and 5, the second peripheral area R4 of the second conductive pad 154 is positioned around the second bonding region R3 of the second conductive pad 154. The second barrier layer 155 conformally surrounds the second conductive pad 154. The third dielectric layer 151 conformally surrounds the second barrier layer 155. In an embodiment, the second conductive pad 154, the second barrier layer 155, and the corner portion 151C of the third dielectric layer 151 may have a circular shape. In another embodiment, the second conductive pad 154, the second barrier layer 155, and the corner portion 151C of the third dielectric layer 151 are not limited to the circular shape, and may have various shapes such as a polygon or an oval.

In an embodiment, a horizontal width W4 of the second bonding region R3 may be about 0.006 μm to about 20 μm. In an embodiment, a horizontal width W5 of the trench T may be about 0.002 μm to about 5 μm. In an embodiment, a horizontal width W6 of the corner portion 151C may be about 0.001 μm to about 3 μm. In an embodiment, a height H4 of the second inner surface TS2 of the trench T may be about 0.001 μm to about 2 μm. In an embodiment, a vertical depth H5 of the corner portion 151C may be about 0.001 μm to about 2 μm. In an embodiment, a height H6 of the first inner surface TS1 of the trench T may be about 2 μm or less.

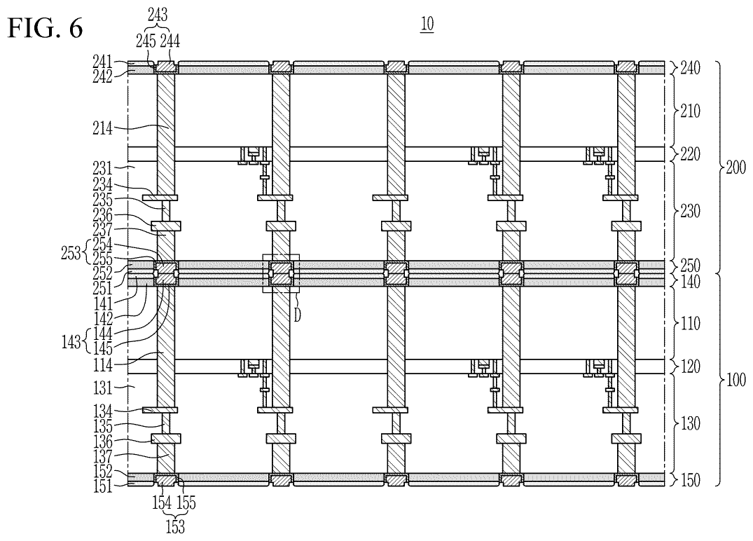

FIG. 6 illustrates a cross-sectional view showing a first semiconductor stacking structure 10 according to an embodiment.

Referring to FIG. 6, the first semiconductor stacking structure 10 includes a first semiconductor die 100 and a second semiconductor die 200. The first semiconductor die 100 and the second semiconductor die 200 may be of the same type. The second semiconductor die 200 may include the same configuration as the first semiconductor die 100. In an embodiment, the first semiconductor die 100 and the second semiconductor die 200 each may be a DRAM.

The first back side bonding structure 140 of the first semiconductor die 100 is bonded to the second front side bonding structure 250 of the second semiconductor die 200 by hybrid bonding.

The first dielectric layer 141 of the first back side bonding structure 140 of the first semiconductor die 100 and the third dielectric layer 251 of the second front side bonding structure 250 of the second semiconductor die 200 are directly bonded by non-metal-non-metal hybrid bonding. Covalent bonding occurs through heat and pressure at an interface between the first dielectric layer 141 of the first back side bonding structure 140 and the third dielectric layer 251 of the second front side bonding structure 250. The first dielectric layer 141 of the first back side bonding structure 140 and the third dielectric layer 251 of the second front side bonding structure 250 are made of the same material, and after hybrid bonding, an interface between the first dielectric layer 141 of the first back side bonding structure 140 and the third dielectric layer 251 of the second front side bonding structure 250 may disappear.

The first bonding pads 143 of the first back side bonding structure 140 of the first semiconductor die 100 and the second bonding pads 253 of the second front side bonding structure 250 of the second semiconductor die 200 are directly bonded by metal-metal hybrid bonding. Metal bonding is achieved by heat and pressure at an interface between the first bonding pads 143 of the first back side bonding structure 140 and the second bonding pads 253 of the second front side bonding structure 250. The first bonding pads 143 of the first back side bonding structure 140 and the second bonding pads 253 of the second front side bonding structure 250 are made of the same material, and after hybrid bonding, an interface between the first bonding pads 143 of the first back side bonding structure 140 and the second bonding pads 253 of the second front side bonding structure 250 may disappear. The first semiconductor die 100 and the second semiconductor die 200 are electrically connected to each other through the first bonding pads 143 of the first back side bonding structure 140 and the second bonding pads 253 of the second front side bonding structure 250.

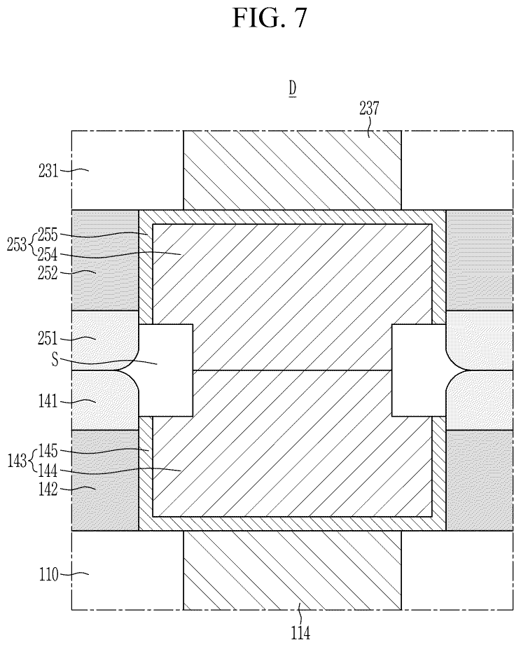

FIG. 7 illustrates a cross-sectional view showing a region D of an embodiment of the first semiconductor stacking structure 10 of FIG. 6.

Hybrid bonding must be performed in a state where a bonding surface of the first back side bonding structure 140 and the second front side bonding structure 250 are flat against each other.

The bonding surface of the first back side bonding structure 140 is formed of first bonding pads 143 and a first dielectric layer 141 surrounding side surfaces of the first bonding pads 143, and the bonding surface of the second front side bonding structure 250 is formed of second bonding pads 253 and a third dielectric layer 251 surrounding side surfaces of the second bonding pads 253, and in the instant case, in a process of performing a chemical mechanical planarization (CMP) process to expose the first bonding pads 143 from the first dielectric layer 141 covering the first bonding pads 143, or in a process of exposing the second bonding pads 253 from the third dielectric layer 251 covering the second bonding pads 253, due to an influence of a difference in selectivity between film quality of the bonding pad and film quality of the dielectric layer, and due to an influence of mechanical processing, the first bonding region R1 of the first bonding pad 143 may be removed more than the first peripheral region R2 of the first bonding pads 143, or dishing may occur in which more of the second bonding region R3 of the second bonding pad 253 is removed than the second peripheral region R4 of the second bonding pads 253.

If the dishing occurs in the first bonding pad 143 and the second bonding pad 253, the first bonding pad 143 has a shape where a slope of a cross-sectional profile increases from the first bonding region R1 to the first peripheral region R2, and the second bonding pad 253 has a shape where the slope of the cross-sectional profile increases from the second bonding region R3 to the second peripheral region R4.

Accordingly, during metal-metal hybrid bonding, the first bonding region R1 of the first bonding pad 143 and the second bonding region R3 of the second bonding pad 253, where bonding must occur, are not bonded to each other, and the first peripheral region R2 of the first bonding pad 143 and the second peripheral area R4 of the second bonding pad 253 are instead bonded to each other. This phenomenon weakens a bonding strength, and is one of main causes of delamination of the first bonding pad 143 and the second bonding pad 253.

According to the present disclosure, the first bonding pad 143 and the second bonding pad 253 may each have a bonding surface having a gently inclined cross-sectional profile by forming the trench T in the first peripheral region R2 of the dished first bonding pad 143 and forming the trench T in the second peripheral region R4 of the dished second bonding pad 253. In addition, a design margin for a thickness of each of the first bonding pad 143 and the second bonding pad 253 set considering that the first bonding pad 143 and the second bonding pad 253 will be dished may be improved. Therefore, factors that impede reliability during bonding of the bonding pads may be eliminated by strengthening the bonding strength of the first bonding pad 143 and the second bonding pad 253.

In addition, if hybrid bonding is performed in a state where the bonding surface of the first back side bonding structure 140 and the second front side bonding structure 250 are not flat due to a deviation in the surface topography or a problem in process technology, etc., vertical lines of the first bonding pads 143 and the second bonding pads 253 that are bonded to each other do not match.

If the bonding surfaces of the first bonding pads 143 and the bonding surfaces of the second bonding pads 253 are misaligned due to mismatch of the vertical lines of the first bonding pads 143 and the second bonding pads 253, the first bonding pads 143 are in contact with the third dielectric layer 251, and the second bonding pads 253 are in contact with the first dielectric layer 141. However, because the first bonding pads 143 and the third dielectric layer 251 which are contacted or the second bonding pads 253 and the first dielectric layer 141 which are contacted are not bonded to each other, cracks may occur at an interface between the first bonding pads 143 and the third dielectric layer 251 or at an interface between the second bonding pads 253 and the first dielectric layer 141. In addition, in the bonding process, a corner of the first dielectric layer 141 or a corner of the third dielectric layer 251 may be broken due to contact impact between the first bonding pads 143 and the third dielectric layer 251 or between the second bonding pads 253 and the first dielectric layer 141.

According to the present disclosure, the first dielectric layer 141 includes a chamfered corner (e.g., a rounded edge) around the first bonding pad 143, the third dielectric layer 251 includes a chamfered corner (e.g., a rounded edge) around the second bonding pad 253, and the first bonding pad 143 and the second bonding pad 153 each include the trench T, and thus an air space S is formed at a boundary between the first back side bonding structure 140 and the second front side bonding structure 250. The air space S is defined by the corners of the first dielectric layer 141, the corners of the third dielectric layer 251, the trench T of the first bonding pad 143, and the trench T of the second bonding pad 253.

In this way, by forming the air space S, in a case of performing hybrid bonding, a space may be secured to prevent the dielectric layer and the bonding pads from coming into contact due to the vertical lines of the bonding surfaces of the first bonding pads 143 of the first back side bonding structure 140 and the second bonding pads 253 of the second front side bonding structure 250 not matching. As a result, in the process of performing the bonding process, cracks may be prevented from occurring or the corners of the first dielectric layer 141 or the corners of the third dielectric layer 251 may be prevented from breaking due to the contact impact between the first bonding pads 143 and the third dielectric layer 251 or between the second bonding pads 253 and the first dielectric layer 141, and reliability may be improved.

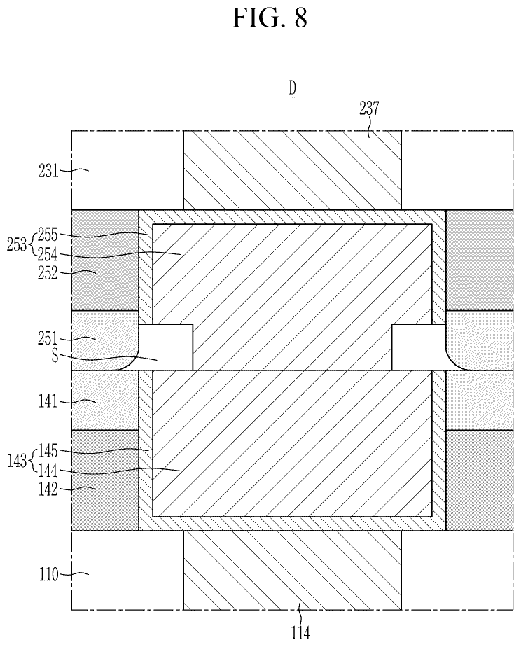

FIG. 8 illustrates a cross-sectional view showing another embodiment of the region D of the first semiconductor stacking structure 10 of FIG. 6.

Referring to FIG. 8, the first dielectric layer 141 surrounds the side surface of the first bonding pad 143. The first dielectric layer 141 does not include a corner portion that is chamfered (M) around the first bonding pad 143. In an embodiment, the first dielectric layer 141 may contact a portion of the side surface of the first barrier layer 145.

The second dielectric layer 142 surrounds the side surface of the first bonding pad 143. In an embodiment, the second dielectric layer 142 may contact a portion of the side surface of the first barrier layer 145.

Each of the first bonding pads 143 includes a first conductive pad 144 and a first barrier layer 145. The first bonding pad 143 does not include a trench. The first conductive pad 144 has a first surface corresponding to the bonding surface and a second surface opposite to the first surface in the vertical direction. The through silicon via (TSV) 114 is positioned on the second surface of the first conductive pad 144. The first conductive pad 144 is formed as a bonding region and does not include a peripheral region around the bonding region. The bonding region has a bonding surface (first surface) that is bonded to a conductive pad of another semiconductor die. The bonding surface has the same level as a level of a surface (bonding surface) of the first dielectric layer 141 and a level of a surface of the first barrier layer 145.

The first barrier layer 145 is disposed between the through silicon via (TSV) 114 and the first conductive pad 144, and electrically connects the through silicon via (TSV) 114 to the first conductive pad 144. The first barrier layer 145 surrounds the side surface of the first conductive pad 144 and the second surface of the first conductive pad 144. The first barrier layer 145 conformally extends along the side surface of the first conductive pad 144 and the second surface of the first conductive pad 144. In an embodiment, the first barrier layer 145 may be provided between the side surface of the first conductive pad 144 and the first dielectric layer 141, between the side surface of the first conductive pad 144 and the second dielectric layer 142, and between the second surface of the first conductive pad 144 and the substrate 110. In an embodiment, a thickness of the first barrier layer 145 may be about 0.01 μm to about 1 μm.

According to the present disclosure, the first semiconductor die 100 may include the first back side bonding structure 140 including the first bonding pad 143 without a trench and the first dielectric layer 141 without a chamfered (M) corner considering a design margin for a thickness of the first bonding pad 143 and a degree of reliability during bonding. The second semiconductor die 200 may include the second front side bonding structure 250 including the second bonding pad 253 with a trench and the third dielectric layer 251 with a chamfered corner.

If the first back side bonding structure 140 of the first semiconductor die 100 and the second front side bonding structure 250 of the second semiconductor die 200 are bonded by performing a hybrid bonding process, the air space S is formed in a space between the second bonding pad 253 on which the trench is formed and the first bonding pad 143 on which the trench is not formed. Accordingly, a space may be secured to prevent the dielectric layer and the bonding pads from coming into contact due to the vertical lines of the bonding surfaces of the first bonding pads 143 of the first back side bonding structure 140 and the second bonding pads 253 of the second front side bonding structure 250 not matching, by forming the air space S.

As a result, in the process of performing the bonding process, cracks may be prevented from occurring or the corners of the first dielectric layer 141 or the corners of the third dielectric layer 251 may be prevented from breaking due to the contact impact of the contact impact between the first bonding pads 143 and the third dielectric layer 251 or between the second bonding pads 253 and the first dielectric layer 141, and reliability may be improved.

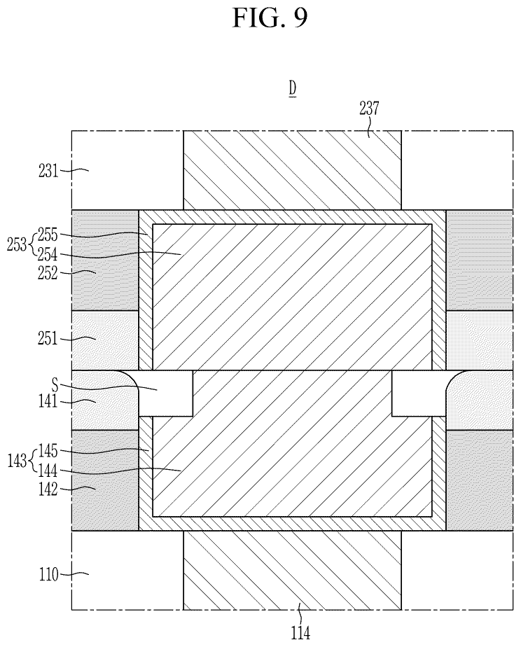

FIG. 9 illustrates a cross-sectional view showing another embodiment of the region D of the first semiconductor stacking structure 10 of FIG. 6.

Referring to FIG. 9, the third dielectric layer 251 surrounds the side surface of the second bonding pad 253. The third dielectric layer 251 does not include a corner portion that is chamfered (M) around the second bonding pad 253. In an embodiment, the third dielectric layer 251 may contact a portion of the side surface of the second barrier layer 255.

The fourth dielectric layer 252 surrounds the side surface of the second bonding pad 253. In an embodiment, the fourth dielectric layer 252 may contact a portion of the side surface of the second barrier layer 255.

The second bonding pad 253 includes a second conductive pad 254 and a second barrier layer 255. The second bonding pad 253 does not include a trench. The second conductive pad 254 has a first surface corresponding to the bonding surface and a second surface opposite to the first surface. A contact plug 237 is positioned on the second surface of the second conductive pad 254. The second conductive pad 254 is formed as a bonding region and does not include a peripheral region around the bonding region. The bonding region has a bonding surface (first surface) that is bonded to a conductive pad of another semiconductor die. The bonding surface has the same level as a level of a surface (bonding surface) of the third dielectric layer 251 and a level of a surface of the second barrier layer 255.

The second barrier layer 255 is disposed between the contact plug 237 and the second conductive pad 254, and electrically connects the contact plug 237 to the second conductive pad 154. The second barrier layer 255 surrounds the side surface of the second conductive pad 254 and the second surface of the second conductive pad 254. The second barrier layer 255 conformally extends along the side surface of the second conductive pad 254 and the second surface of the second conductive pad 254. In an embodiment, the second barrier layer 255 may be provided between the side surface of the second conductive pad 254 and the third dielectric layer 251, between the side surface of the second conductive pad 254 and the fourth dielectric layer 252, and between the second surface of the second conductive pad 254 and the wiring layer 230. In an embodiment, a thickness of the second barrier layer 255 in the vertical direction may be about 0.01 μm to about 1 μm.

According to the present disclosure, the second semiconductor die 200 includes the second front side bonding structure 250 including the second bonding pad 253 without a trench and the third dielectric layer 251 without a chamfered (M) corner considering a design margin for a thickness of the second bonding pad 253 and a degree of reliability during bonding. The first semiconductor die 100 may include the first back side bonding structure 140 including the first bonding pad 143 with a trench and the first dielectric layer 141 with a chamfered corner.

If the first back side bonding structure 140 of the first semiconductor die 100 and the second front side bonding structure 250 of the second semiconductor die 200 are bonded by performing a hybrid bonding process, the air space S is formed in a space between the first bonding pad 143 on which the trench is formed and the second bonding pad 253 on which the trench is not formed. Accordingly, a space may be secured to prevent the dielectric layer and the bonding pads from coming into contact due to the vertical lines of the bonding surfaces of the first bonding pads 143 of the first back side bonding structure 140 and the second bonding pads 253 of the second front side bonding structure 250 not matching, by forming the air space S.

As a result, in the process of performing the bonding process, cracks may be prevented from occurring or the corners of the first dielectric layer 141 or the corners of the third dielectric layer 251 may be prevented from breaking due to the contact impact between the first bonding pads 143 and the third dielectric layer 251 or between the second bonding pads 253 and the first dielectric layer 141, and reliability may be improved.

FIG. 10 illustrates a cross-sectional view showing a semiconductor package 11 according to an embodiment.

Referring to FIG. 10, the semiconductor package 11 includes a plurality of semiconductor stacking structures 10. The semiconductor package 11 has a structure in which first semiconductor dies 100 and second semiconductor dies 200 are alternately stacked. The semiconductor package 11 has a structure in which dies of the same type are stacked. In an embodiment, the semiconductor package 11 may include a high bandwidth memory (HBM).

A high-bandwidth memory (HBM) is a high-performance three-dimensional (3D) stacked dynamic random access memory (DRAM). The high-bandwidth memory (HBM) is manufactured by performing hybrid bonding or stacking memory dies vertically using micro bumps to form a single memory stack. The high-bandwidth memory (HBM) may implement short latency and high bandwidth compared to conventional DRAM products together by having multiple memory channels through a memory stack in which memory dies are vertically stacked, and may reduce a total area occupied by individual DRAMs on a printed circuit board (PCB), which is advantageous in terms of high bandwidth compared to area and reducing power consumption.

The high bandwidth memory includes a buffer die 101, first semiconductor dies 100, second semiconductor dies 200, and a molding material 900.

The buffer die 101 is positioned lowest in high bandwidth memory. When exchanging data between devices with different data processing speeds, processing units, and usage times, data loss may occur due to differences in data processing speeds, processing units, and usage times between devices. To prevent this loss, the buffer die 101 is positioned, and Information in exchanging data between the first semiconductor dies 100 and an external device and between the second semiconductor dies 200 and an external device is temporarily stored in the buffer die 101. The buffer die 101 arranges the order of the data and then passes the data in order in a case of transmitting data to the first semiconductor dies 100 and the second semiconductor dies 200, or receiving data from the first semiconductor dies 100 and the second semiconductor dies 200.

The first semiconductor dies 100 and the second semiconductor dies 200 are positioned on the buffer die 101. A second semiconductor die 200T without through-silicon vias is disposed at an upper portion of the memory stack. The first semiconductor dies 100 are bonded to the buffer die 101 by hybrid bonding. The first semiconductor dies 100 and the second semiconductor dies 200 are bonded to each other by hybrid bonding.

The molding material 900 is positioned on the buffer die 101, and molds the first semiconductor dies 100 and the second semiconductor dies 200. For example, the molding material 900 may surround the sides of the first semiconductor dies 100 and the second semiconductor dies 200. The molding material 900 serves to protect and insulate the first semiconductor dies 100 and the second semiconductor dies 200. In an embodiment, the molding material 900 may be formed of a thermosetting resin such as an epoxy resin. In an embodiment, the molding material 900 may be an epoxy molding compound (EMC).

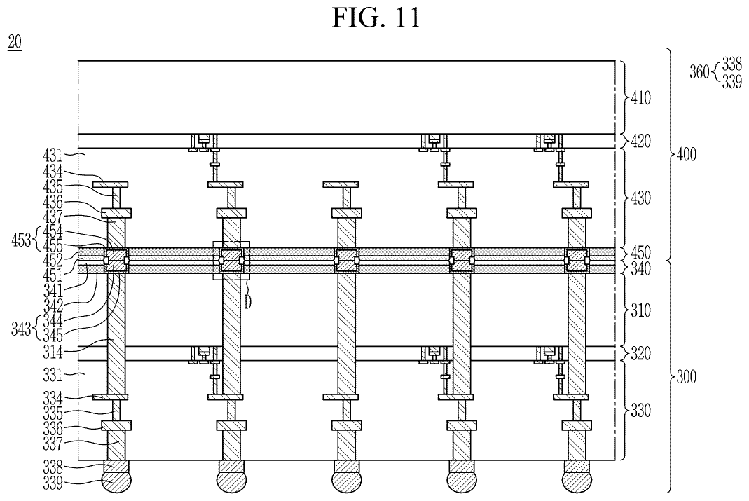

FIG. 11 illustrates a cross-sectional view showing a second semiconductor stacking structure 20 according to an embodiment. Contents described regarding the region D of an embodiment of the first semiconductor stacking structure 10 in FIGS. 7 to 9 may be applied to the second semiconductor stacking structure 20 of the embodiment of FIG. 11.

Referring to FIG. 11, the second semiconductor stacking structure 20 includes a third semiconductor die 300 and a fourth semiconductor die 400. The third semiconductor die 300 and the fourth semiconductor die 400 are of different types. In an embodiment, the third semiconductor die 300 may include a central processing unit (CPU) or a graphics processing unit (GPU). In an embodiment, the fourth semiconductor die 400 may include at least one of a memory, a communication chip, a controller, and a sensor.

The third semiconductor die 300 includes a connection structure 360 to be connected to other devices. The connection structure 360 includes connection pads 338 and connection members 339. In an embodiment, the connection members 339 may include micro bumps. In an embodiment, the fourth semiconductor die 400 may not include through silicon vias extending from the front side to the back side of the substrate 410. In an embodiment, the fourth semiconductor die 400 may include the back side bonding structure. Regarding structures of the third semiconductor die 300 and the fourth semiconductor die 400 other than those described above, what has been described with respect to the first semiconductor die 100 may be applied.

A third back side bonding structure 340 of the third semiconductor die 300 is bonded to a fourth front side bonding structure 450 of the fourth semiconductor die 400 by hybrid bonding.

The first dielectric layer 341 of the third back side bonding structure 340 of the third semiconductor die 300 and the third dielectric layer 451 of the fourth front side bonding structure 450 of the fourth semiconductor die 400 are directly bonded by non-metal-non-metal hybrid bonding. Covalent bonding occurs through heat and pressure at an interface between the first dielectric layer 341 of the third back side bonding structure 340 and the third dielectric layer 451 of the fourth front side bonding structure 450. The first dielectric layer 341 of the third back side bonding structure 340 and the third dielectric layer 451 of the fourth front side bonding structure 450 are made of the same material, and after hybrid bonding, an interface between the first dielectric layer 341 of the third back side bonding structure 340 and the third dielectric layer 451 of the fourth front side bonding structure 450 may disappear.

First bonding pads 343 of the third back side bonding structure 340 of the third semiconductor die 300 and second bonding pads 453 of the fourth front side bonding structure 450 of the fourth semiconductor die 400 are directly bonded by metal-metal hybrid bonding. Metal bonding is achieved by heat and pressure at an interface between the first bonding pads 343 of the third back side bonding structure 340 and the second bonding pads 453 of the fourth front side bonding structure 450. The first bonding pads 343 of the third back side bonding structure 340 and the second bonding pads 453 of the fourth front side bonding structure 450 are made of the same material, and after hybrid bonding, an interface between the first bonding pads 343 of the third back side bonding structure 340 and the second bonding pads 453 of the fourth front side bonding structure 450 may disappear. The third semiconductor die 300 and the fourth semiconductor die 400 are electrically connected to each other through the first bonding pads 343 of the third back side bonding structure 340 and the second bonding pads 453 of the fourth front side bonding structure 450.

FIG. 12 illustrates a cross-sectional view showing the semiconductor package 21 according to another embodiment.

Referring to FIG. 12, the semiconductor package 21 includes a redistribution structure 510, a semiconductor stacking structure 20 on the redistribution structure 510, conductive posts 600 on the redistribution structure 510, and a molding material 610 for molding the third semiconductor die 300 on the redistribution structure 510. The semiconductor stacking structure 20 includes a third semiconductor die 300 and a fourth semiconductor die 400. A footprint of the third semiconductor die 300 is included (e.g., contained) within a footprint of the fourth semiconductor die 400. The fourth semiconductor die 400 has a larger horizontal area than the third semiconductor die 300. The third semiconductor die 300 is die of a different type from the fourth semiconductor die 400. The semiconductor package 21 has a structure in which dies of different types are stacked. In an embodiment, the semiconductor package 21 may include a system on chip (SoC). In an embodiment, the semiconductor package 21 may include a 3-dimensional integrated circuit (3DIC). In an embodiment, the third semiconductor die 300 may be a bottom die of the 3D integrated circuit. In an embodiment, the fourth semiconductor die 400 may be a top die of the 3D integrated circuit. The third semiconductor die 300 and the fourth semiconductor die 400 may be bonded together using hybrid bonding, using any of the bonding pads and dielectric layers according to embodiments of the disclosure.

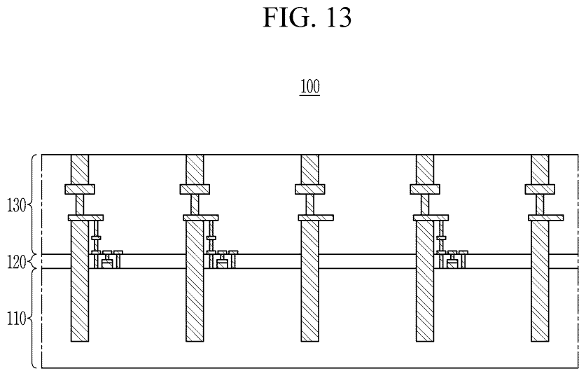

FIG. 13 to FIG. 34 illustrate cross-sectional views for describing a manufacturing method for the first front side bonding structure 150 of the first semiconductor die 100. The manufacturing method for the first front side bonding structure 150 of the first semiconductor die 100 of FIGS. 13 to 34 may also be applied to a manufacturing method for the back side bonding structure 140 of the first semiconductor die 100.

FIG. 13 illustrates a cross-sectional view showing a step of providing the first semiconductor die 100 with the through silicon vias (TSV) 114 formed in a front end semiconductor process.

A process of forming the through silicon vias (TSV) 114 in the front end semiconductor process will be described as follows. First, holes are formed to penetrate from the front side to the back side of the substrate 110, and the through-silicon vias (TSV) 114 are formed by filling the holes with a first conductive material. In an embodiment, the holes may be formed by deep etching. In an embodiment, the holes may be formed by a laser. In an embodiment, holes of the through silicon vias (TSV) 114 may be filled with a first conducting material by electrolytic plating. In an embodiment, the holes of the through silicon vias (TSV) 114 may be filled with the first conducting material by physical vapor deposition (PVD). In an embodiment, the first conductive material may include at least one of tungsten, aluminum, copper, and an alloy thereof. In addition, a barrier layer (not illustrated) may be formed between the through silicon vias (TSV) 114 and an insulating material of the substrate 110, the active layer 120, and the wiring layer 130. In an embodiment, the barrier layer (not illustrated) may include at least one of titanium, tantalum, titanium nitride, tantalum nitride, and an alloy thereof.

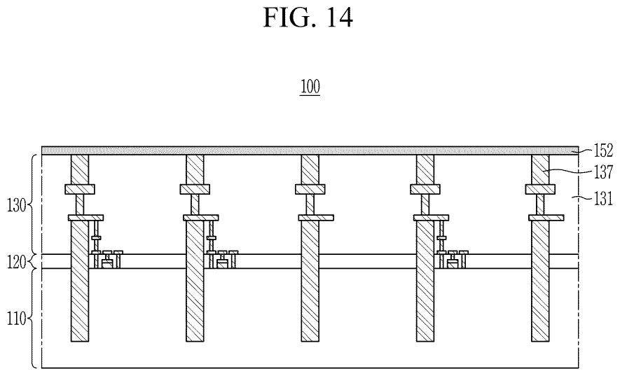

FIG. 14 illustrates a cross-sectional view showing a step of forming the fourth dielectric layer 152.

Referring to FIG. 14, the fourth dielectric layer 152 is deposited on the intermetal dielectric (IMD) 131 of the wiring layer 130 and on an exposed surface of the contact plug 137 of the wiring layer 130. In an embodiment, the fourth dielectric layer 152 may be formed through an atomic layer deposition (ALD) process or a chemical vapor deposition (CVD) process.

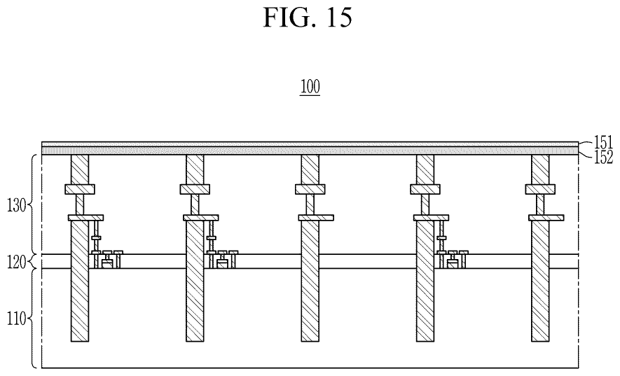

FIG. 15 illustrates a cross-sectional view showing a step of forming the third dielectric layer 151.

Referring to FIG. 15, the third dielectric layer 151 is deposited on the fourth dielectric layer 152. In an embodiment, the fourth dielectric layer 152 may be formed through an atomic layer deposition (ALD) process or a chemical vapor deposition (CVD) process.

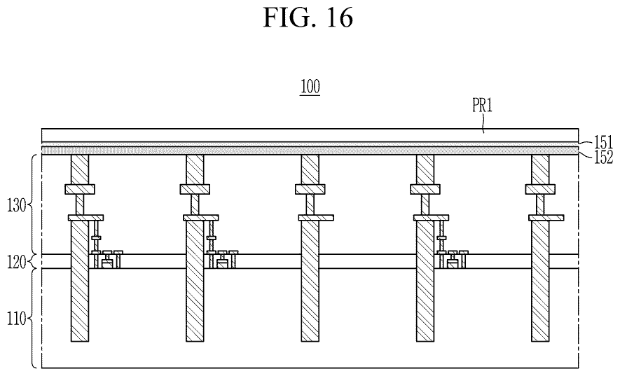

FIG. 16 illustrates a cross-sectional view showing a step of forming a first photoresist PR1 on the third dielectric layer 151.

Referring to FIG. 16, the first photoresist PR1 is deposited on the third dielectric layer 151. In an embodiment, the first photoresist PR1 may be formed through spin coating. In an embodiment, the first photoresist PR1 may include an organic polymer resin comprising a photoactive material.

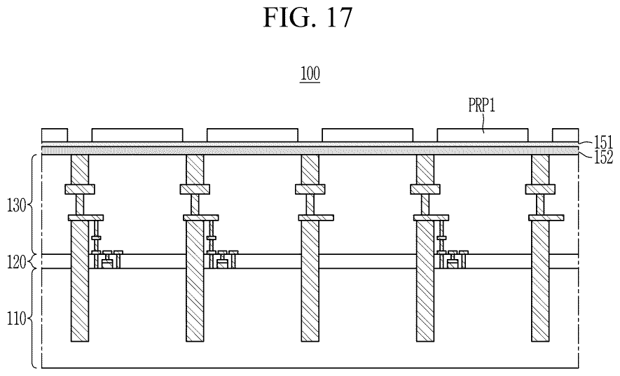

FIG. 17 illustrates a cross-sectional view showing a step of forming a first photoresist pattern PRP1 by exposing and developing the first photoresist PR1.

Referring to FIG. 17, the first photoresist PR1 is exposed and developed to form the first photoresist pattern PRP1.

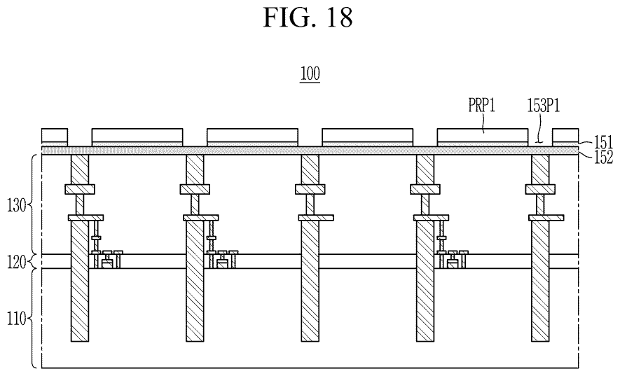

FIG. 18 illustrates a cross-sectional view showing a step of exposing the fourth dielectric layer 152 by forming a pattern on the third dielectric layer 151.

Referring to FIG. 18, first openings 153P1 are formed in the third dielectric layer 151 by etching the third dielectric layer 151 exposed through the first photo resist pattern PRP1. The fourth dielectric layer 152 is exposed through the first openings 153P1. In an embodiment, a process of etching the third dielectric layer 151 may be performed by dry etching.

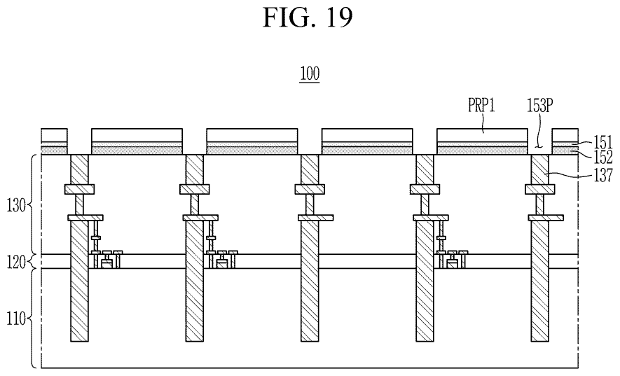

FIG. 19 illustrates a cross-sectional view showing a step of exposing the contact plugs 137 by forming a pattern on the fourth dielectric layer 152.

Referring to FIG. 19, openings 153P are formed in the fourth dielectric layer 152 by etching the fourth dielectric layer 152 exposed through the first opening 153P1.

The intermetal dielectric (IMD) 131 and the contact plugs 137 are exposed through the openings 153P. In an embodiment, a process of etching the fourth dielectric layer 152 may be performed by dry etching.

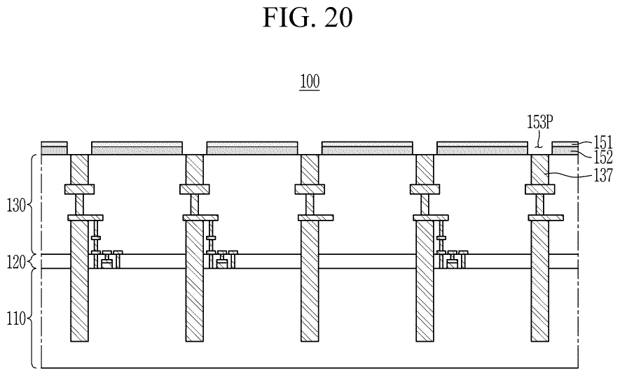

FIG. 20 illustrates a cross-sectional view showing a step of removing the first photoresist pattern PRP1.

Referring to FIG. 20, the first photoresist pattern PRP1 is removed. In an embodiment, the first photoresist pattern PRP1 may be removed by at least one of etching, ashing, and strip.

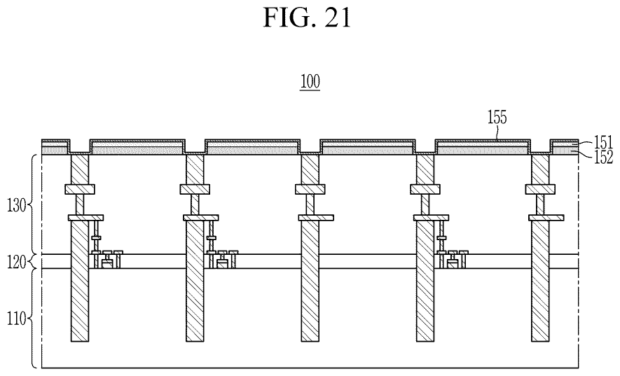

FIG. 21 illustrates a cross-sectional view showing a step of forming the second barrier layer 155.

Referring to FIG. 21, the second barrier layer 155 is deposited on the third dielectric layer 151 and in the openings 153P. In an embodiment, the second barrier layer 155 may include titanium (Ti) or a titanium alloy. In an embodiment, the second barrier layer 155 may be formed through a physical vapor deposition (PVD) process. In an embodiment, the second barrier layer 155 may be formed through a sputtering process.

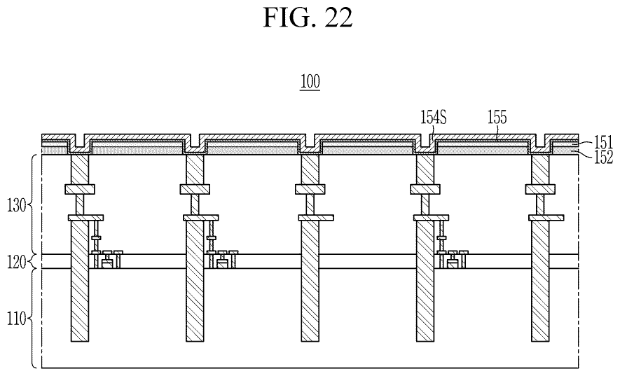

FIG. 22 illustrates a cross-sectional view showing forming a seed metal layer 154S.

Referring to FIG. 22, the seed metal layer 154S is conformally deposited on the second barrier layer 155. In an embodiment, the seed metal layer 154S may include copper. In an embodiment, the seed metal layer 154S is formed by electroless plating. In an embodiment, a cleaning process or metal catalyst activation pretreatment process may be performed prior to the electroless plating. In another embodiment, the seed metal layer 154S is formed by sputtering.

FIG. 23 illustrates a cross-sectional view showing forming a conductive material layer 154M on the seed metal layer 154S.

Referring to FIG. 23, the conductive material layer 154M is deposited on the seed metal layer 154S. In an embodiment, the conductive material layer 154M may include copper. In an embodiment, the conductive material layer 154M is formed by electroplating. A conductive material layer 154M is formed by growing a metal film from the previously formed seed metal layer 154S by electroplating. In an embodiment, an annealing process may be performed after the conductive material layer 154M is formed.

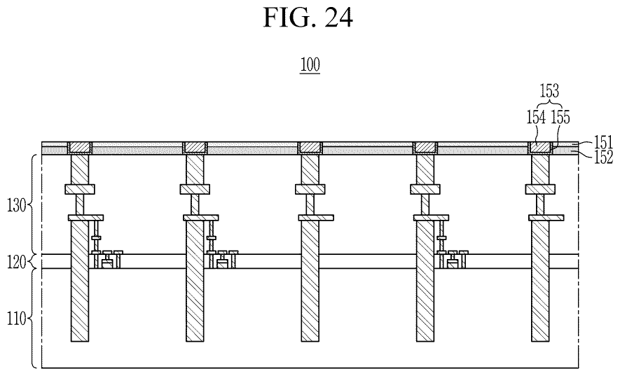

FIG. 24 illustrates a cross-sectional view showing performing a planarization process on the third dielectric layer 151 and the conductive material layer 154M.

Referring to FIG. 24, chemical mechanical polishing (CMP) is performed to level upper surfaces of the third dielectric layer 151 and the second bonding pads 153. A CMP process is applied to planarize the upper surfaces of the third dielectric layer 151 and the conductive material layer 154M. Second bonding pads 153 are formed by planarizing the upper surface of the conductive material layer 154M.

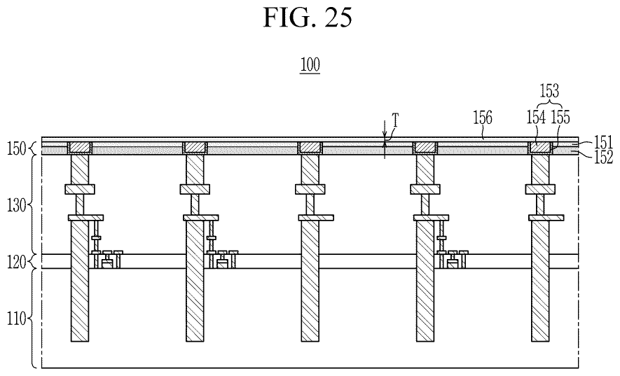

FIG. 25 illustrates a cross-sectional view showing forming a sacrificial dielectric layer 156 on the third dielectric layer 151 and the second bonding pads 153.

Referring to FIG. 25, the sacrificial dielectric layer 156 is deposited on the planarized third dielectric layer 151 and the second bonding pads 153. In an embodiment, the sacrificial dielectric layer 156 may be formed through an atomic layer deposition (ALD) process or a chemical vapor deposition (CVD) process.

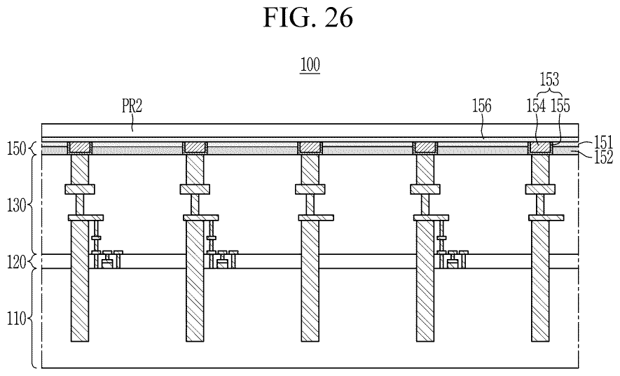

FIG. 26 illustrates a cross-sectional view showing forming a second photoresist PR2 on the sacrificial dielectric layer 156.

Referring to FIG. 26, the second photoresist PR2 is deposited on the sacrificial dielectric layer 156. In an embodiment, the second photoresist PR2 may be formed through spin coating. In an embodiment, the second photoresist PR2 may include an organic polymer resin comprising a photoactive material.

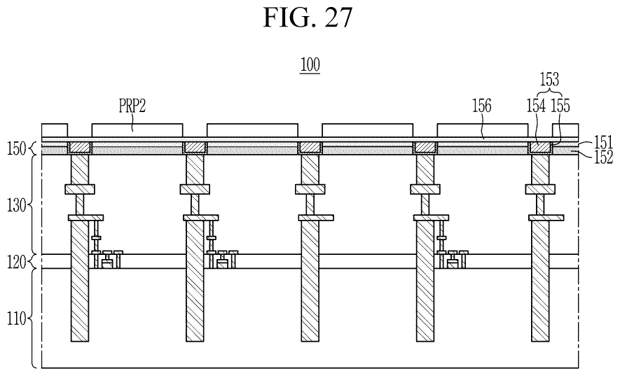

FIG. 27 illustrates a cross-sectional view showing forming a second photoresist pattern PRP2 by exposing and developing the second photoresist PR2.

Referring to FIG. 27, the second photoresist PR2 is exposed and developed to form the second photoresist pattern PRP2.

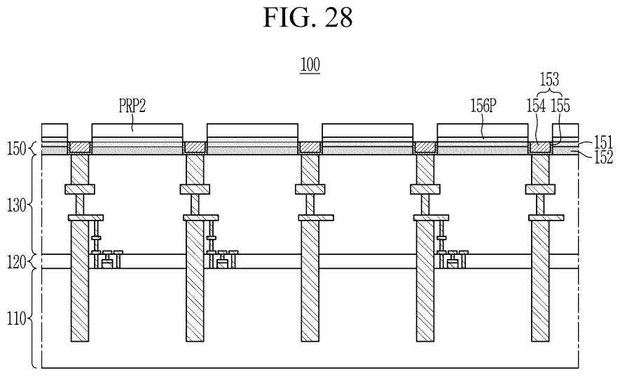

FIG. 28 illustrates a cross-sectional view showing exposing bonding surfaces of the second bonding pads 153 by forming a pattern on the sacrificial dielectric layer 156.

Referring to FIG. 28, the sacrificial dielectric layer 156 exposed from the second photoresist PR2 is etched to expose the planarized bonding surfaces of the second bonding pads 153. In an embodiment, a process of etching the sacrificial dielectric layer 156 may be performed by dry etching.

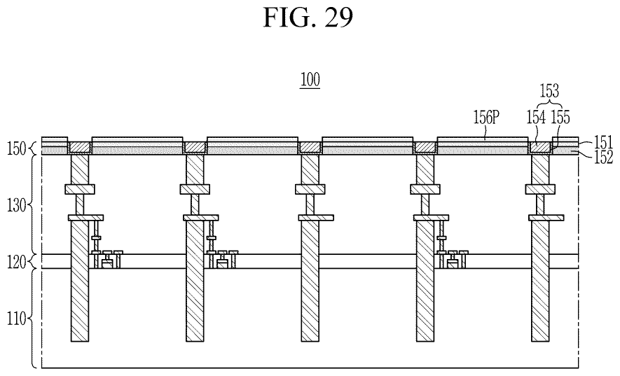

FIG. 29 illustrates a cross-sectional view showing removing the second photoresist pattern PRP2.

Referring to FIG. 29, the second photoresist pattern PRP2 is removed. In an embodiment, the second photoresist pattern PRP2 may be removed by at least one of etching, ashing, and strip.

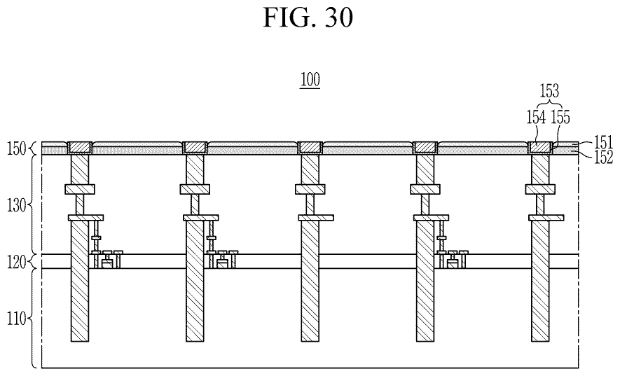

FIG. 30 illustrates a cross-sectional view showing removing the remaining sacrificial dielectric layer 156 and performing a chamfering process on the third dielectric layer 151 around the second bonding pad 153.

Referring to FIG. 30, the remaining sacrificial dielectric layer 156 is removed, and the chamfering process is performed on the third dielectric layer 151 around the second bonding pad 153. In an embodiment, a process of removing the remaining sacrificial dielectric layer 156 and a process of performing the chamfering process on the third dielectric layer 151 around the second bonding pad 153 may be performed by wet etching. In an embodiment, the process of removing the remaining sacrificial dielectric layer 156 and the process of performing the chamfering process on the third dielectric layer 151 around the second bonding pad 153 may be performed simultaneously by a single etching process.

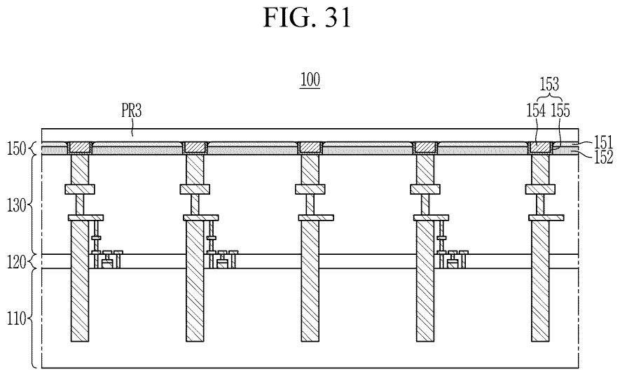

FIG. 31 illustrates a cross-sectional view showing forming a third photoresist PR3 on the chamfered third dielectric layer 151 and the second bonding pads 153.

Referring to FIG. 31, the third photoresist PR3 is deposited on the chamfered third dielectric layer 151 and the second bonding pads 153. In an embodiment, the third photoresist PR3 may be formed through spin coating. In an embodiment, the third photoresist PR3 may include an organic polymer resin comprising a photoactive material.

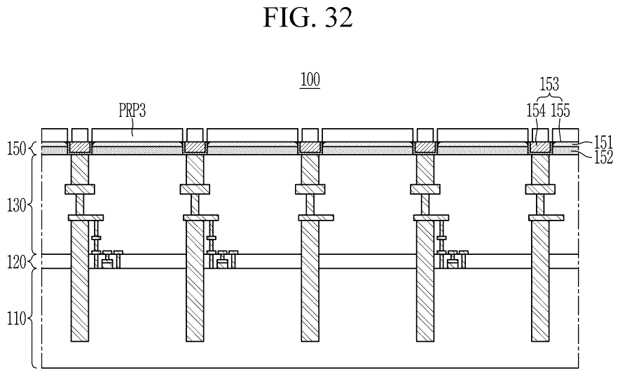

FIG. 32 illustrates a cross-sectional view showing forming a third photoresist pattern PRP3 by exposing and developing the third photoresist PR3.

Referring to FIG. 32, the third photoresist PR3 is exposed and developed to form the third photoresist pattern PRP3.

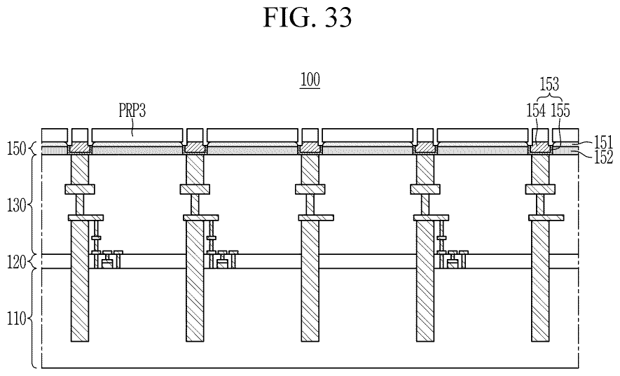

FIG. 33 illustrates a cross-sectional view showing forming the trench T in the second bonding pads 153.

Referring to FIG. 33, the trench T is formed by etching the second peripheral region R4 of the second conductive pad 154 of the second bonding pads 153 and the second barrier layer 155 exposed from the third photoresist pattern PRP3. In an embodiment, a process of etching the sacrificial dielectric layer 156 may be performed by wet etching.

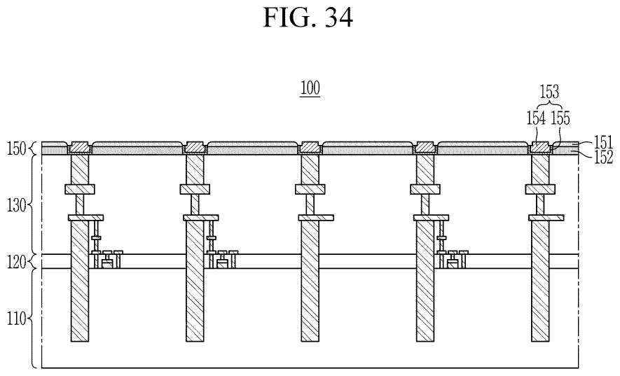

FIG. 34 illustrates a cross-sectional view showing removing the third photoresist pattern PRP3.

Referring to FIG. 34, the third photoresist pattern PRP3 is removed. In an embodiment, the third photoresist pattern PRP3 may be removed by at least one of etching, ashing, and strip.

Thereafter, the substrate 110 of the first semiconductor die 100 may undergo a thinning process on the back surface of the substrate 110 to expose the through silicon vias 114, and the back side bonding structure 140 may be formed through the same process as in FIGS. 13 to 34.

While this disclosure has been described in connection with what is presently considered to be practical embodiments, it is to be understood that the invention is not limited to the disclosed embodiments, but, on the contrary, is intended to cover various modifications and equivalent arrangements included within the spirit and scope of the inventive concept.

What is claimed is:

1. A semiconductor chip comprising:
a substrate;
a back side bonding structure on a back surface of the substrate; and
a front side bonding structure on a front side of the substrate,
wherein the back side bonding structure and the front side bonding structure each comprise:
a dielectric layer; and
bonding pads extending through the dielectric layer,
wherein each of the bonding pads comprises:
a conductive pad including a bonding region and a peripheral region around the bonding region; and
a barrier layer between a side surface of the peripheral region and the dielectric layer, and
wherein each of the bonding pads of the back side bonding structure, each of the bonding pads of the front side bonding structure, or both each of the bonding pads of the back side bonding structure and each of the bonding pads of the front side bonding structure includes a trench in which the peripheral region and the barrier layer are recessed relative to a level of a bonding surface of the bonding region.

2. The semiconductor chip of claim 1, wherein
the dielectric layer includes edge portions, each edge portion of the edge portions surrounding a respective bonding pad of the bonding pads, and
each edge portion of the edge portions is chamfered around a corresponding one of the bonding pads.

3. The semiconductor chip of claim 2, wherein
the corner portion has a rounded shape.

4. The semiconductor chip of claim 2, wherein
the dielectric layer further includes inner side portions,
each of the inner side portions extends from a corresponding one of the edge portions,
an inner side portion of the inner side portions is adjacent to the bonding pads that includes the trench, and
the inner side portion adjacent to the bonding pads that includes the trench is exposed through the trench.

5. The semiconductor chip of claim 1, wherein
in the bonding pad that includes the trench, the peripheral region and the barrier layer are exposed through the trench.

6. The semiconductor chip of claim 1, wherein
the trench includes:
a first inner surface defined by an inner surface of the dielectric layer;
a second inner surface defined by a side surface of the bonding region; and
a trench bottom surface defined by a surface of the peripheral region and a surface of the barrier layer.

7. The semiconductor chip of claim 6, wherein
when viewed in plan view, the trench has a ring shape extending along the trench bottom surface between the first inner surface and the second inner surface.

8. The semiconductor chip of claim 1, wherein
in the bonding pad that includes the trench, the bonding region protrudes beyond the peripheral region in a direction perpendicular to the bonding surface of the bonding region.

9. The semiconductor chip of claim 1, wherein
the barrier layer extends conformally along a side surface of the peripheral region and a surface of the conductive pad opposite the bonding surface.

10. A semiconductor package comprising:
a first semiconductor die including a first substrate and a first back side bonding structure on a back surface of the first substrate; and
a second semiconductor die including a second substrate and a second front side bonding structure on a front side of the second substrate, wherein the second front side bonding structure is bonded to the first back side bonding structure,
wherein the first back side bonding structure comprises:
a first dielectric layer; and
first bonding pads extending through the first dielectric layer,
wherein each of the first bonding pads comprises:
a first conductive pad include a first bonding region and a first peripheral region around the first bonding region; and
a first barrier layer between a side surface of the first peripheral region and the first dielectric layer,
wherein the second front side bonding structure comprises:
a second dielectric layer; and
second bonding pads extending through the second dielectric layer,
wherein each of the second bonding pads comprises:
a second conductive pad including a second bonding region and a second peripheral region around the second bonding region; and
a second barrier layer between a side surface of the second peripheral region and the second dielectric layer,
wherein each of the first bonding pads includes a first trench in which the first peripheral region and the first barrier layer are recessed relative to a level of a bonding surface of the first bonding region, each of the second bonding pads includes a second trench in which the second peripheral region and the second barrier layer are recessed relative to a level of a bonding surface of the second bonding region, or each of the first bonding pads includes the first trench and each of the second bonding pads includes the second trench.

11. The semiconductor package of claim 10, further comprising
air spaces,
wherein each of the air spaces is defined by at least one of the first trench and the second trench.

12. The semiconductor package of claim 10, wherein
the first dielectric layer is directly bonded to the second dielectric layer.

13. The semiconductor package of claim 10, wherein
the first dielectric layer and the second dielectric layer each include a silicon nitride.

14. The semiconductor package of claim 10, wherein
the first bonding region is directly bonded to the second bonding region.

15. The semiconductor package of claim 10, wherein
the first semiconductor die is of the same type of die as the second semiconductor die.

16. The semiconductor package of claim 10, wherein
the first semiconductor die is a different type of die from the second semiconductor die.

17. A manufacturing method for a semiconductor chip, comprising:
forming a dielectric layer and bonding pads extending through the dielectric layer on a surface of a substrate, each of the bonding pads comprising:
a conductive pad; and
a barrier layer between a side surface of the conductive pad and the dielectric layer;
forming a sacrificial dielectric layer on the dielectric layer and the bonding pads;
forming a pattern on the sacrificial dielectric layer to expose bonding surfaces of the bonding pads;
etching the pattern of the sacrificial dielectric layer and performing a chamfering process on the dielectric layer around the bonding pads; and
forming a trench in each of the bonding pads such that the barrier layer and a peripheral region of the conductive pad are recessed with respect to a bonding region of each of the bonding pads.

18. The manufacturing method of claim 17, wherein
the step of etching the pattern of the sacrificial dielectric layer and the step of performing the chamfering process on the dielectric layer around the bonding pads are performed simultaneously by a single etching process.

19. The manufacturing method of claim 18, wherein
the single etching process is a wet etching process.

20. The manufacturing method of claim 17, wherein
the step of forming the trench in each of the bonding pads is performed by a wet etching process.
